(19) United States
(12) Patent Application Publication
(10) Pub. No.: US 2026/0018210 A1
(43) Pub. Date: Jan. 15, 2026

(54) SEMICONDUCTOR DEVICE

(71) Applicant: Renesas Electronics Corporation, Tokyo (JP)

(72) Inventors: Kenichiro TAKIGUCHI, Tokyo (JP); Shinji TANAKA, Tokyo (JP)

(21) Appl. No.: 19/256,824

(22) Filed: Jul. 1, 2025

(30) Foreign Application Priority Data
Jul. 10, 2024 (JP) 2024-111126

(51) Int. Cl. G11C 15/04; G06F 16/903

(52) U.S. Cl. CPC G11C 15/04; G06F 16/90339

(57) ABSTRACT

A semiconductor device capable of operating a content addressable memory at higher speed is provided. The semiconductor device 1 includes a memory array 4 with a master block 2 storing a first portion of a bit string constituting data entries, and a slave block 3 storing the remaining second portion of the bit string, and a search unit 21 included in the master block 2 to determine a match between a portion corresponding to the first portion of the search data and any of the first portions of the data entries. Master block 2 controls to activate the slave block 3 in response to the start of determination by the search unit 21, and controls to continue the activation or inactivate the slave block 3 according to the result of the determination by the search unit 21.

### CROSS-REFERENCE TO RELATED APPLICATIONS

The disclosure of Japanese Patent Application No. 2024-111126 filed on Jul. 10, 2024, including the specification, drawings and abstract is incorporated herein by reference in its entirety.

### BACKGROUND

The present invention relates to a semiconductor device, specifically to a semiconductor device that includes a content addressable memory (CAM) with the function of determining matches between multiple data entries and search data.

There are disclosed techniques listed below.
[Patent Document 1] Japanese Unexamined Patent Application Publication No. 2023-114100

A storage device known as a search memory or content addressable memory (CAM) searches for data words (also referred to as data entries) stored within it that match a search word, and outputs the address if a matching data word is found.

CAMs include BCAM (Binary CAM) and TCAM (Ternary CAM). Each memory cell in a BCAM stores information as either “0” or “1”. In contrast, each memory cell in a TCAM can store information as “0”, “1”, or “Don't Care”. “Don't Care” indicates that either “0” or “1” is acceptable.

TCAMs are widely used in network routers for address searching and access control. To accommodate larger capacities, TCAMs typically have multiple memory arrays, with search operations executed simultaneously on each array.

### SUMMARY

Patent Document 1 describes dividing a memory array into multiple parts in the bit direction and stopping the search operation of the subsequent memory array if all entries in the preceding memory array are mismatched.

However, in Patent Document 1, the search operation of the subsequent memory array is executed after obtaining the search results of the preceding memory array. Therefore, if multiple subsequent memory arrays are provided, the delay time until the control signal indicating search execution reaches the final memory array may limit the speed of the entire internal reference memory.

The embodiments described later were made in view of such issues, and other problems and novel features will become apparent from the description and accompanying drawings of this specification.

A semiconductor device according to one embodiment includes a content addressable memory with a memory array that comprises a first block storing the first portion of a bit string constituting a data entry, and a second block storing the second portion excluding the first portion. The first block controls the activation of the second block in response to the start of determination by a first search circuit that determines the match between any of the first portions and the corresponding portion of the search data and controls the continuation or deactivation of the second block based on the result of the determination by the first search circuit.

According to the aforementioned embodiment, the content addressable memory can operate at a higher speed.

### BRIEF DESCRIPTION OF THE DRAWINGS

FIG. 1 is a schematic diagram of a semiconductor device according to the first embodiment.

FIG. 2 shows the basic operation of the semiconductor device in FIG. 1.

FIG. 3 shows the basic operation of the semiconductor device in FIG. 1.

FIG. 4 shows the basic operation of the semiconductor device in FIG. 1.

FIG. 5 shows a case where the slave block is divided into eight parts.

FIG. 6 is a circuit diagram of the master block.

FIG. 7 is a circuit diagram of the timing generation circuit.

FIG. 8 is a circuit diagram of the SL driver.

FIG. 9 is a circuit diagram of the ML driver.

FIG. 10 is a circuit diagram of the All-Miss determination circuit.

FIG. 11 is a circuit diagram of the SLEN generation circuit.

FIG. 12 is a timing chart showing the operation of the SLEN generation circuit.

FIG. 13 is a timing chart showing the operation of the master block in FIG. 6.

FIG. 14 is a schematic diagram of a semiconductor device according to the second embodiment.

FIG. 15 is a schematic diagram showing an application example of the embodiment.

### DETAILED DESCRIPTION

In the following embodiments, for convenience, explanations may be divided into multiple sections or embodiments, when necessary, but unless specifically stated otherwise, they are not unrelated to each other, and one may be a modification, detail, or supplementary explanation of the other. Also, in the following embodiments, when referring to the number of elements, etc. (including quantity, numerical values, amounts, ranges, etc.), unless specifically stated otherwise or clearly limited to a specific number in principle, it is not limited to that specific number and may be more or less than that specific number.

Furthermore, in the following embodiments, the constituent elements (including element steps, etc.) are not necessarily essential unless specifically stated otherwise or clearly considered essential in principle. Similarly, in the following embodiments, when referring to the shapes, positional relationships, etc. of components, unless specifically stated otherwise or clearly considered otherwise in principle, it is assumed to include those that are substantially approximate or similar to those shapes, etc. The same applies to the above numerical values and ranges.

The circuit elements constituting each functional block of the embodiment are not particularly limited but are formed on a semiconductor substrate such as single-crystal silicon using known integrated circuit technologies such as CMOS (complementary MOS transistor). In the embodiment, a MOSFET (Metal Oxide Semiconductor Field Effect Transistor) is used as an example of a MISFET (Metal Insulator Semiconductor Field Effect Transistor), but it does not exclude non-oxide films as gate insulating films. In the embodiment, a p-channel MOSFET and an n-channel MOSFET are referred to as pMOS and nMOS transistors, respectively.

Hereinafter, embodiments of the present invention will be described in detail with reference to the drawings. In all the drawings for explaining the embodiments, the same members are denoted by the same reference numerals in principle, and repetitive descriptions thereof are omitted.

### First Embodiment

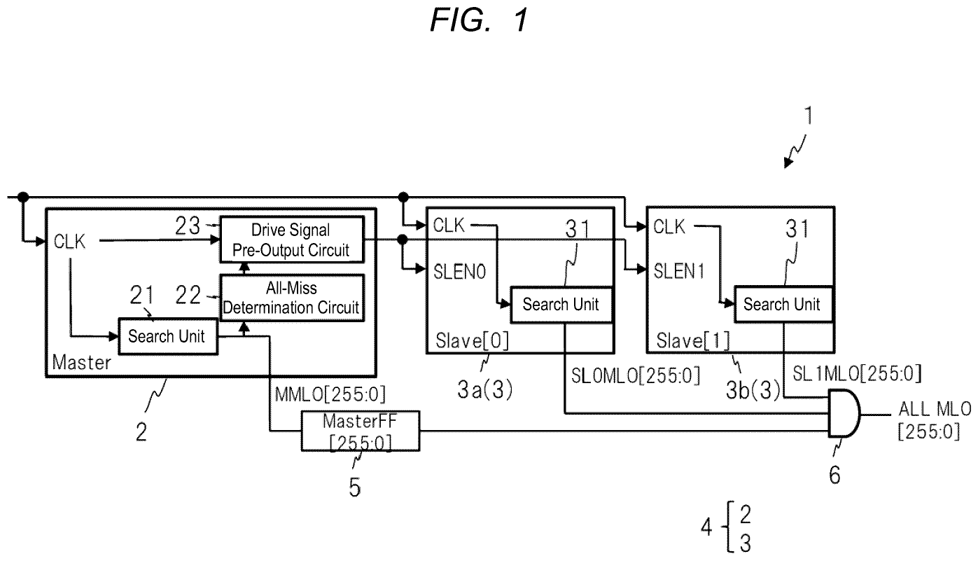

FIG. 1 shows a schematic diagram of a semiconductor device according to this embodiment. This embodiment describes a content addressable memory divided into multiple memory blocks that sequentially execute search operations along the column direction for a memory multiple content addressable memory cells arranged in a matrix to store data entries (hereinafter sometimes abbreviated as entries).

### Outline Configuration of This Embodiment

Referring to FIG. 1, a content addressable memory is described as an example of a semiconductor device. Semiconductor device 1 (content addressable memory) includes a master block 2, a slave block 3, a master FF (flip-flop) 5, and a logic AND circuit 6. The master block 2 and the slave block 3 together form the memory array 4.

Master block 2 has a memory array composed of, for example, 256 entries of 64-bit TCAM cells (not shown in FIG. 1). The master block 2 stores 64 bits of data from the data entry for 256 entries. That is, the master block 2 functions as the first block storing the first portion of the bit string constituting the data entry. Master block 2 also includes search unit 21, an All-Miss determination circuit 22, and a drive signal pre-output circuit 23.

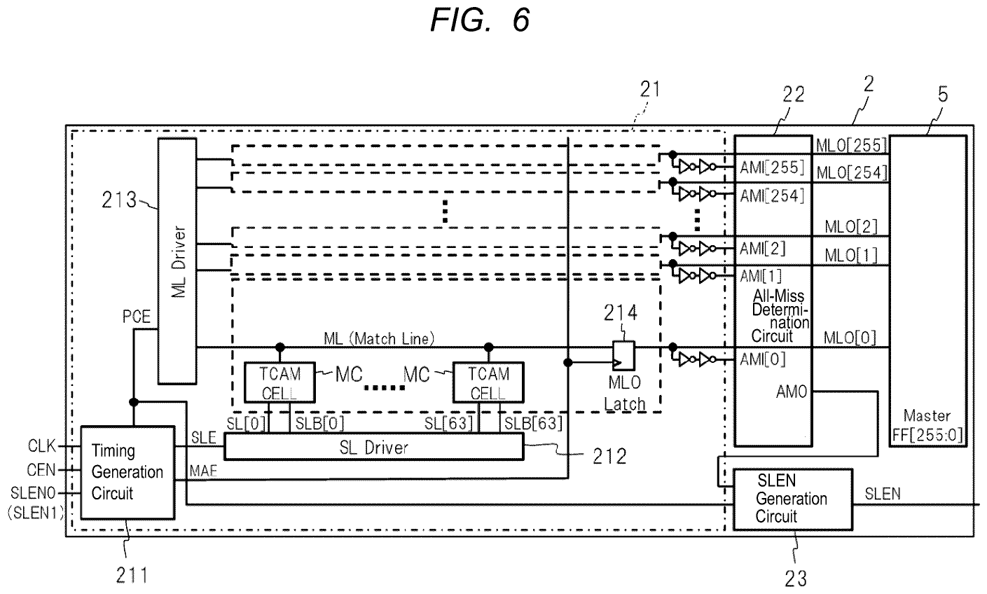

The search unit 21 includes a timing generation circuit 211, an SL driver 212, an ML driver 213, etc. (see FIG. 6). The search unit 21 searches whether the bit string of the portion corresponding to the master block 2 among the search data input to the semiconductor device 1 (content addressable memory) matches each entry stored in the memory array 4 and outputs the search result. The search result (determination result) is output as MMLO [255:0]. That is, the search unit 21 functions as the first search circuit. The detailed circuit and operation of search unit 21 will be described later.

The All-Miss determination circuit 22 continues the assertion of the slave drive signal (SLEN) output by the drive signal pre-output circuit 23 if there is at least one entry determined to match the search data as a result of the search by the search unit 21, and negates the slave drive signal output by the drive signal pre-output circuit 23 if there is no entry determined to match the search data. The detailed circuit and operation of the All-Miss determination circuit 22 will be described later.

The drive signal pre-output circuit 23 outputs a slave drive signal to activate the slave block 3 in response to the start of operation of the master block 2. It also outputs a slave drive signal to activate or deactivate the slave block 3 according to the search result of the search unit 21 under the control of the All-Miss determination circuit 22. In the configuration of FIG. 1, the slave drive signal is output commonly (on the same signal line) to the slave blocks 3a and 3b. The detailed circuit and operation of the drive signal pre-output circuit 23 will be described later.

The slave block 3 has a memory array composed of, for example, 256 entries of 92-bit TCAM cells (not shown in FIG. 1). The slave block 3 stores the data of the portion of the data entry excluding the 64 bits of the first portion for 256 entries. That is, the slave block 3 functions as the second block storing the remaining second portion excluding the first portion of the data entry. The slave block 3 also includes a search unit 31. Additionally, in FIG. 1, there are two slave blocks, 3a and 3b, included as slave block 3, and both slave blocks 3a and 3b have the same configuration.

Slave blocks 3a and 3b function as multiple sub-blocks that store each of the multiple third portions constituting the second portion of the data entry. The slave blocks 3a and 3b determine the match between the third portion stored in each and the corresponding portion of the search data's third portion.

The search unit 31 has a basic configuration identical to that of search unit 21. Search unit 31 searches and outputs the determination result of whether the bit string of the portion corresponding to the slave block 3 among the search data input to the semiconductor device 1 (content addressable memory) matches the entry stored in the memory array. The search result (determination result) of slave block 3a is output as SLOMLO [255:0], and the search result of slave block 3b is output as SLIMLO [255:0]. In other words, the search unit 31 functions as a second search circuit.

The master FF5 is a register for delaying the search result of the master block 2, MMLO [255:0], by one clock. The AND circuit 6 outputs the logical AND of the one-clock delayed MMLO [225:0], SLOMLO [255:0], and SLIMLO [255:0]. In other words, the AND circuit 6 functions as a match detection circuit that determines the match between the search data and the data entry by the logical AND of the determination results of the master block 2 and the slave blocks 3a and 3b.

The semiconductor device 1 with the configuration shown in FIG. 1 first performs the search operation with the master block 2 in the first clock, and the slave block 3 performs the search operation in the next second clock. Therefore, the output of the AND circuit 6, ALL MLO [255:0], is determined in the second clock.

### Basic Operation of This Embodiment

For example, in the circuit described in Patent Document 1, the slave drive signal for activating the slave block 3 is output starting from the result of the master block 2. Therefore, it is necessary to wait for the slave drive signal to reach the end of the slave block 3, which constrains the speed-up of the entire content addressable memory. In this embodiment, the slave drive signal is preemptively output starting from the output of the clock signal (CLK) to activate the slave block 3. Then, as soon as the search result of the master block 2 is known, the slave drive signal is stopped as needed to inactivate the slave block 3. As a result, when the search data is supplied to the slave block 3 and the search operation starts, the slave drive signal indicating activation has reached all the slave blocks 3, enabling the speed-up of the entire content addressable memory.

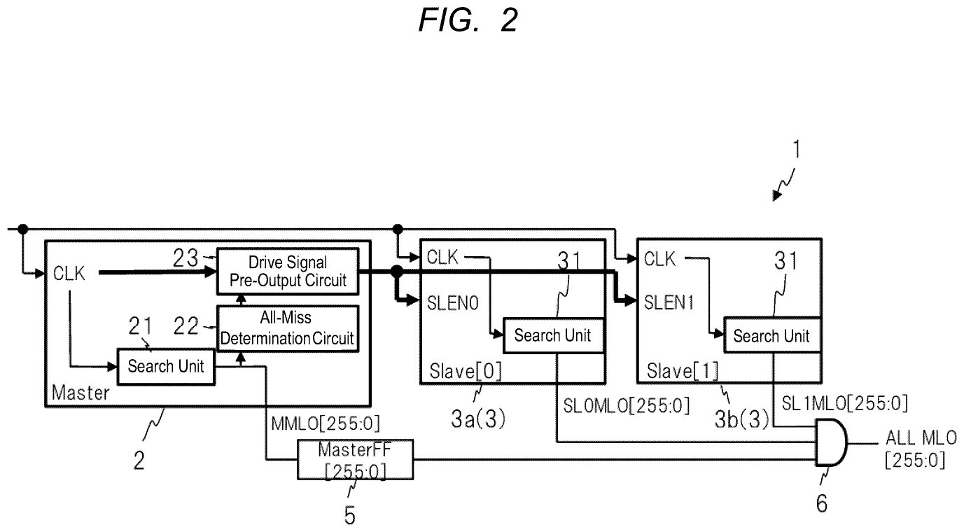

Next, the basic operation of this embodiment will be explained with reference to FIGS. 2 to 4. FIG. 2 is a diagram where the search results of the master block 2, slave block 3a, and 3b are all matches (Hit). In FIG. 2, the search unit 21 starts the search operation triggered by, for example, the rising edge of the clock signal CLK. In parallel with the search operation, the drive signal preemptive circuit 23 outputs the slave drive signal SLEN to the slave blocks 3a and 3b (asserts the slave drive signal SLEN). Consequently, SLEN0 of slave block 3a and SLEN1 of slave block 3b are asserted, activating slave blocks 3a and 3b. Therefore, slave blocks 3a and 3b are in a state where they can start the search operation triggered by the next rising edge of the clock signal CLK (bold line in FIG. 2).

Subsequently, a match (Hit) is output as the search result of the search unit 21. Since the search result is a match, the All-Miss determination circuit 22 controls the drive signal preemptive circuit 23 to continue asserting the slave drive signal SLEN. In other words, the activation of the slave block 3 is continued. Therefore, the search operation of slave blocks 3a and 3b is started triggered by the next rising edge of the clock signal CLK. Consequently, the search (determination) by search unit 31 is performed.

In FIG. 2, since the search results of the master block 2, slave block 3a, and 3b are all matches (Hit), ALL MLO also outputs a match (Hit). That is, since the slave drive signal SLEN has reached slave blocks 3a and 3b at the time of the next rising edge of the clock, slave blocks 3a and 3b operate normally, outputting a match (Hit), and ALL MLO also outputs a match (Hit).

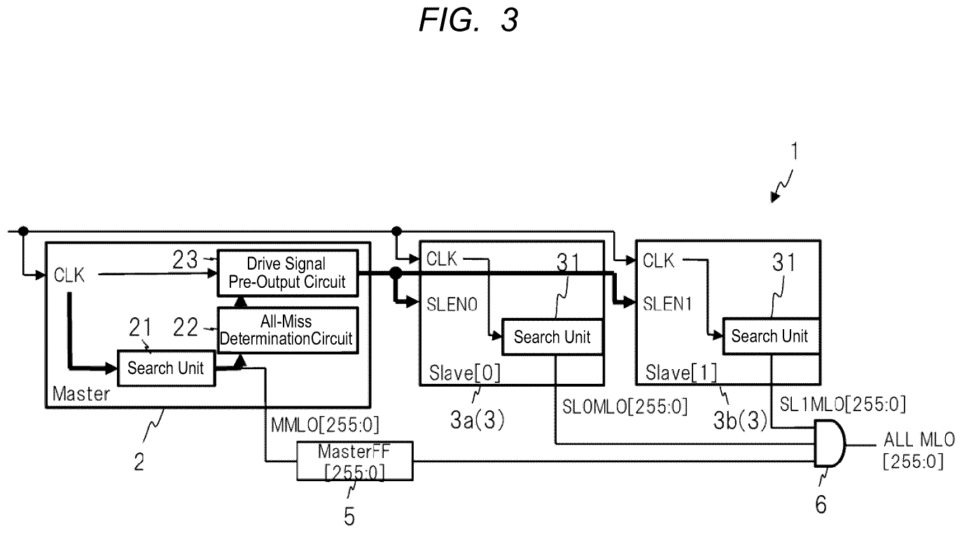

FIG. 3 is a diagram where the search result of the master block 2 is a mismatch (Miss). In FIG. 3, the search unit 21 starts the search operation triggered by, for example, the rising edge of the clock signal CLK. In parallel with the search operation, the drive signal preemptive circuit 23 asserts the slave drive signal SLEN. Consequently, SLEN0 of slave block 3a and SLEN1 of slave block 3b are asserted, activating slave blocks 3a and 3b. Therefore, they are in a state where they can start the search operation triggered by the next rising edge of the clock signal CLK.

Subsequently, a mismatch (Miss) is output as the search result of the search unit 21. Since the search result is a mismatch, the All-Miss determination circuit 22 controls the drive signal preemptive circuit 23 to negate the slave drive signal SLEN, inactivating the slave block 3 (bold line in FIG. 3). Consequently, SLEN0 of slave block 3a and SLEN1 of slave block 3b are negated, and even if the next rising edge of the clock signal CLK comes, the search operation is not performed in slave blocks 3a and 3b. Therefore, the search (determination) by the search unit 31 is not performed.

In FIG. 3, since the search result of the master block 2 is a mismatch (Miss), ALL MLO outputs a mismatch (Miss) regardless of the search results of slave blocks 3a and 3b.

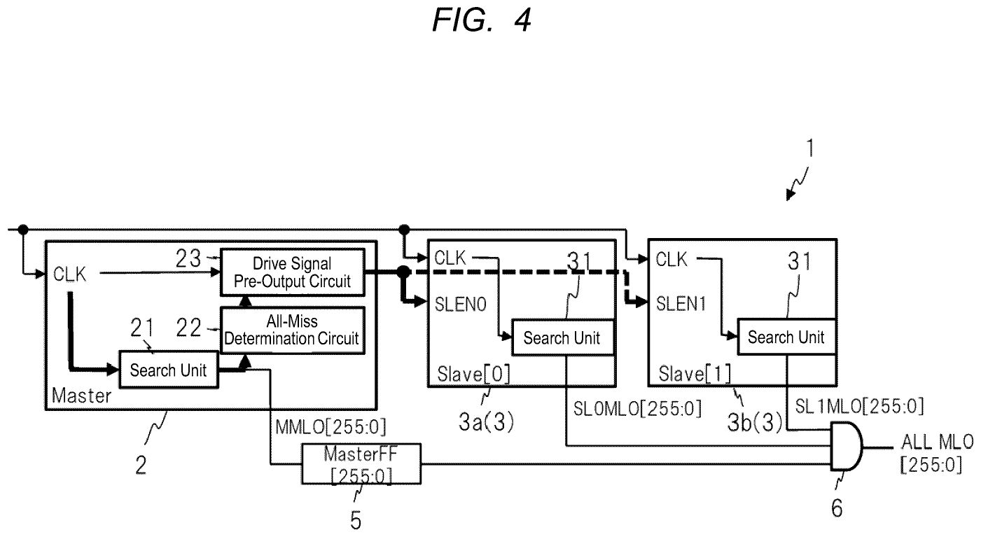

FIG. 4 is a diagram where the search result of the master block 2 is a mismatch (Miss) and the change of the slave drive signal SLEN does not reach the end of the slave block 3b in time. In FIG. 4, the search unit 21 starts the search operation triggered by, for example, the rising edge of the clock signal CLK. In parallel with the search operation, the drive signal preemptive circuit 23 asserts the slave drive signal SLEN. Consequently, SLEN0 of slave block 3a and SLEN1 of slave block 3b are asserted, activating slave blocks 3a and 3b. Therefore, they are in a state where they can start the search operation triggered by the next rising edge of the clock signal CLK.

Subsequently, a mismatch (Miss) is output as the search result of the search unit 21. Since the search result is a mismatch, the All-Miss determination circuit 22 controls the drive signal preemptive circuit 23 to negate the slave drive signal SLEN, inactivating the slave block 3 (bold solid line in FIG. 4). Consequently, SLEN0 of slave block 3a is negated, and even if the next rising edge of the clock signal CLK comes, the search operation is not performed in slave block 3a.

On the other hand, since SLEN1 of slave block 3b is not negated in time for the rising edge of the clock signal CLK, the search operation is performed in slave block 3b (bold dashed line in FIG. 4). However, since a mismatch has already been determined as the search result of master block 2, the AND circuit 6 has determined a low level (Lo) indicating a mismatch, and even if slave block 3b outputs a match (Hit), it does not affect ALL MLO.

In FIG. 4, since the search result of the master block 2 is a mismatch (Miss), ALL MLO outputs a mismatch (Miss) regardless of the search results of slave blocks 3a and 3b.

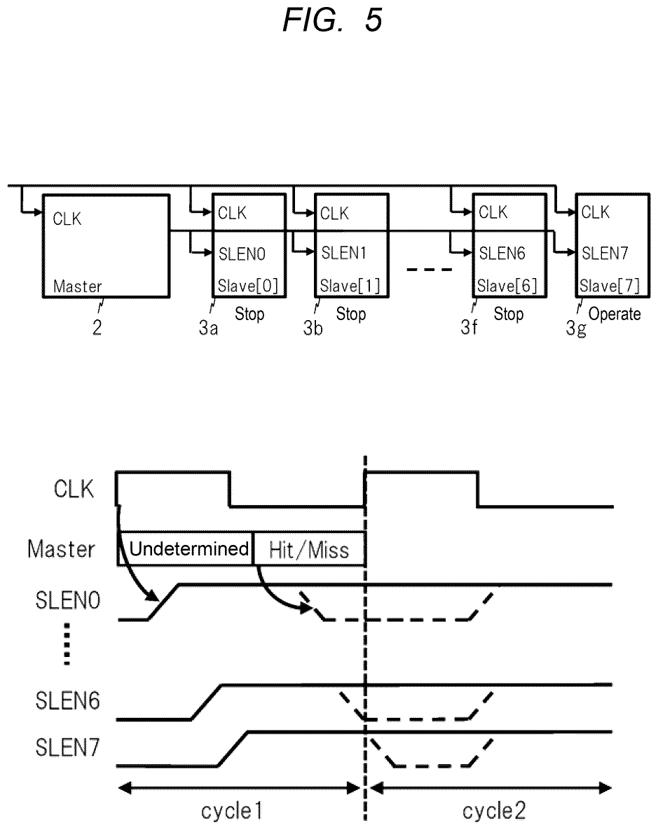

In FIG. 2 and others, the slave block 3 was divided into two, but as shown in FIG. 5, it may be further divided into more (eight in FIG. 5). In this case, by preemptively outputting the slave drive signal SLEN as in this embodiment, each slave block 3 can be in an operable state during the first clock, and it is more effective to control the slave drive signal SLEN according to the search result of the master block 2.

As shown in FIG. 5, for example, when divided into eight, due to the RC delay of the slave drive signal SLEN, it may not reach the end slave block 3g by cycle 2 (lower dashed line in FIG. 5). In that case, slave block 3g operates, but since other slave blocks 3a, 3b, . . . , 3f are stopped, there are more stopped blocks when viewed as a whole slave block 3, resulting in a significant power-saving effect. Also, since control is performed to stop the slave block 3 when the search result of the master block 2 is a mismatch, the result of a mismatch is determined as a whole due to the mismatch of the master block 2, and the slave drive signal SLEN is less likely to be a constraint on circuit operation speed-up.

### Circuit Configuration Example of the Present Embodiment

The circuit configuration example of the present embodiment will be described with reference to FIGS. 6 to 12. It should be noted that the circuits shown below are merely examples, and other circuit configurations may be used as long as they can achieve equivalent functions. Additionally, the logic levels indicating the assertion and negation of each signal may be appropriately modified. FIG. 6 shows the circuit of master block 2. Note that the part included in the search section 21 of the configuration shown in FIG. 6 is also the same for the slave block 3. Therefore, in FIG. 6, SLEN0 (SLEN1) is also described as an input, but in master block 2, SLEN0 may be fixed to Hi.

Also, the SLEN generation circuit 23 described in FIG. 6 is a circuit having the same function as the drive signal precedence circuit 23 described in FIG. 1, etc. Furthermore, although master FF5 was described outside the master block 2 in FIG. 1, etc., it may be included in master block 2 as shown in FIG. 6.

As described in FIG. 6, the search section 21 includes a timing generation circuit 211, an SL driver 212, and an ML driver 213. The memory array is divided for each entry (dashed line part), and each entry has multiple TCAM cells MC. Then, a match line ML is provided corresponding to the multiple TCAM cells MC provided along the column included in the memory cell row direction.

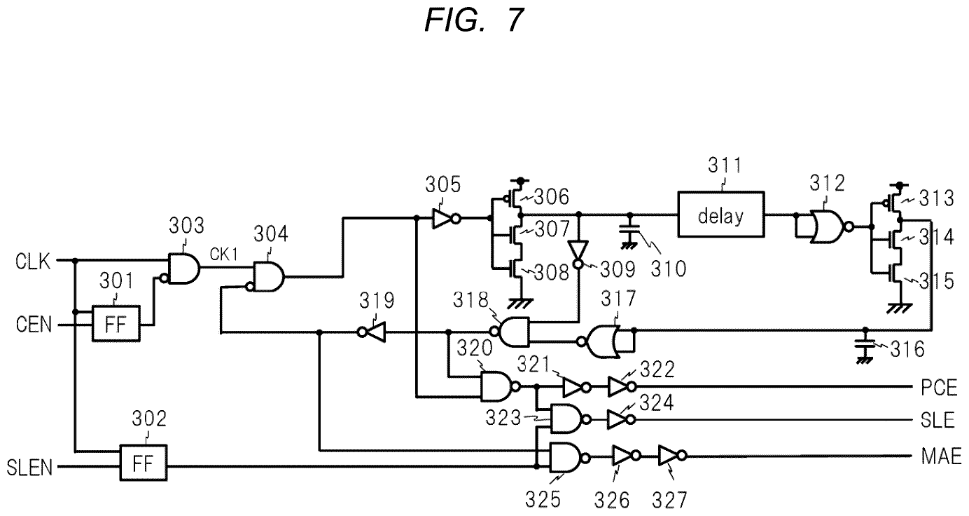

FIG. 7 is an example of a circuit diagram of the timing generation circuit 211. The timing generation circuit 211 includes flip-flops 301, 302, AND circuits 303, 304, inverters 305, 309, 319, 321, 322, 324, 326, 327, pMOS transistors 306, 313, nMOS transistors 307, 308, 314, 315, a capacitive element 310, a delay circuit 311, NOR circuits 312, 317, and NAND circuits 318, 320, 323, 325.

The flip-flop 301 captures and outputs the control signal CEN based on the clock signal CLK. The control signal CEN is a control signal that controls the enable/disable of the clock signal CLK. The flip-flop 302 captures and outputs the slave drive signal SLEN based on the clock signal CLK.

The AND circuit 303 receives the clock signal CLK and the inverted output of the flip-flop 301 and outputs the result of the AND logic operation. The AND circuit 304 receives the output of the AND circuit 303 and the inverted output of the inverter 319 and outputs the result of the AND logic operation.

The inverter 305 inverts the output of the AND circuit 304 and outputs it to the gate of the pMOS transistor 306, the gate of the nMOS transistor 307, and the gate of the nMOS transistor 308.

The pMOS transistor 306 and the nMOS transistors 307, 308 are connected in series between the power supply potential (voltage Vcc level) and the ground potential (voltage Vss level). A control signal is output from the connection node between the pMOS transistor 306 and the nMOS transistor 307.

The inverter 309 inverts and outputs the control signal output from the connection node between the pMOS transistor 306 and the nMOS transistor 307.

The delay circuit 311 delays the control signal output from the connection node between the pMOS transistor 306 and the nMOS transistor 307 by a predetermined time and outputs it. The delay circuit 311 can be configured, for example, with a multi-stage inverter. Also, a capacitive element 310, whose other electrode is connected to the ground potential (voltage Vss level), is connected to the input node of the delay circuit 311.

The NOR circuit 312 inverts the output signal of the delay circuit 311 and outputs it to the gate of the pMOS transistor 313, the gate of the nMOS transistor 314, and the gate of the nMOS transistor 315.

The pMOS transistor 313 and the nMOS transistors 314, 315 are connected in series between the power supply potential and the ground potential. A control signal is output from the connection node between the pMOS transistor 313 and the nMOS transistor 314.

The NOR circuit 317 inverts the control signal output from the connection node between the pMOS transistor 313 and the nMOS transistor 314 and outputs it to the NAND circuit 318. Also, a capacitive element 316, whose other electrode is connected to the ground potential, is connected to the input node of the NOR circuit 317.

The NAND circuit 318 receives the output signal of the NOR circuit 317 and the output signal of the inverter 309 and outputs the result of the NAND logic operation. The inverter 319 inverts and outputs the output signal of the NAND circuit 318.

The NAND circuit 320 receives the output signal of the AND circuit 304 and the output signal of the NAND circuit 318 and outputs the result of the NAND logic operation. The inverters 321, 322 output the output of the NAND circuit 320 as the control signal PCE.

The NAND circuit 323 receives the output signal of the NAND circuit 320 and the output signal of the flip-flop 302 and outputs the result of the NAND logic operation. The inverter 324 inverts and outputs the output signal of the NAND circuit 323 as the control signal SLE.

The NAND circuit 325 receives the output signal of the inverter 319 and the output signal of the flip-flop 302 and outputs the result of the NAND logic operation. The inverters 326, 327 output the output of the NAND circuit 325 as the control signal MAE.

The timing generation circuit 211 is a circuit that generates control signals PCE, MAE, and SLE triggered by the clock signal CLK. The control signals PCE and SLE are asserted simultaneously with the input of the clock signal CLK, and they are negated at the timing when they return through the delay circuit 311. At the timing of this negation, the control signal MAE is asserted, and the All-Miss determination input AMI and the match signal output line MLO (see FIG. 6) are confirmed.

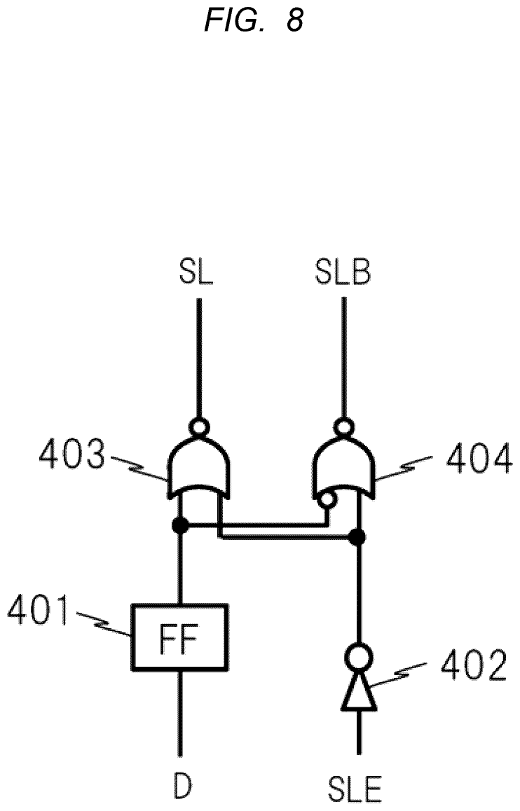

FIG. 8 is an example of the circuit of the SL driver 212. The SL driver 212 includes a flip-flop 401, an inverter 402, and NOR circuits 403, 404. FIG. 8 is a circuit corresponding to one search line pair SL, SLB, and in practice, multiple circuits of FIG. 8 are provided according to the number of bits of the entry (search data).

The flip-flop 401 captures the search data supplied to the data terminal D based on the clock signal CLK and outputs it to the NOR circuits 403, 404. The inverter 402 inverts and outputs the control signal SLE.

NOR circuit 403 receives the output signal of the flip-flop 401 and the output signal of the inverter 402 and outputs the result of the NOR logic operation as the search line SL. The NOR circuit 404 receives the inverted output signal of the flip-flop 401 and the output signal of the inverter 402 and outputs the result of the NOR logic operation as the search line SLB.

The SL driver 212 is a circuit that asserts the search line pair SL, SLB to each TCAM cell MC. When the control signal SLE becomes Hi, the search data set in the data terminal D is asserted to the search line pair SL, SLB.

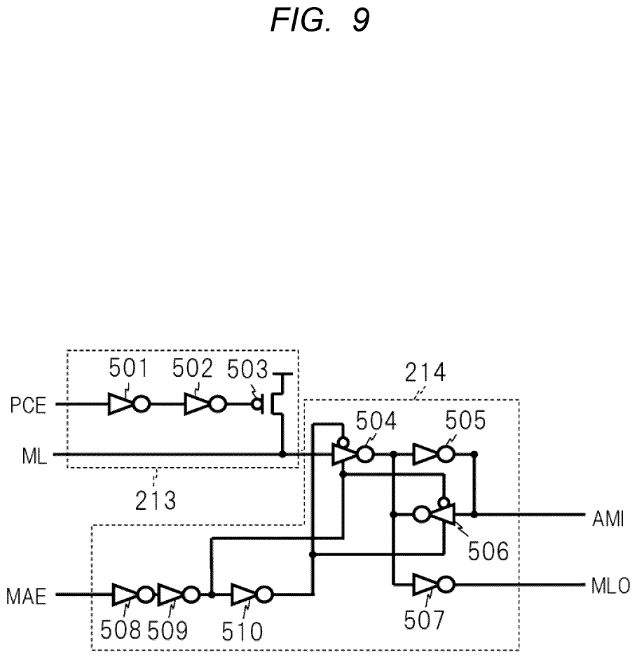

FIG. 9 is an example of the circuit of ML driver 213. FIG. 9 is a circuit corresponding to one match line ML, and in practice, the circuit of FIG. 9 is provided according to the number of match lines ML (number of entries). The ML driver 213 includes inverters 501, 502 and a pMOS transistor 503.

The inverters 501 and 502 output the control signal PCE to the gate of the pMOS transistor 503. The pMOS transistor 503 is connected between the power supply potential (voltage Vcc level) and the match line ML. The ML driver 213 is a circuit that drives the match line ML. When the control signal PCE is Lo, the match line ML is precharged, and when the control signal PCE is Hi, the precharge is cut.

Also, FIG. 9 describes the circuit of the MLO Latch 214. The MLO Latch 214 includes inverters 504, 505, 506, 507, 508, 509, 510.

The inverter 504 outputs the inverted signal of the match line ML when the control signal is input. The inverter 505 outputs the inverted signal of the output signal of the inverter 504 or the inverter 506 as the All-Miss determination input AMI.

The inverter 506 outputs the inverted signal of the output signal of the inverter 505 when the control signal is input. The inverter 507 outputs the inverted signal of the output signal of the inverter 504 to the match signal output line MLO when a signal is output from the inverter 504. Also, the inverter 507 outputs the inverted signal of the output signal of the inverter 506 to the match signal output line MLO when a signal is output from the inverter 506. The inverters 508, 509, 510 output the control signal MAE and the inverted signal of the control signal MAE as the control signals of the inverters 504 and 506.

The MLO Latch 214 transmits the data of the match line ML to the match signal output line MLO and the All-Miss determination input AMI when the control signal MAE is asserted at the timing when the match line ML is confirmed.

In detail, when the control signal MAE is asserted, the inverter 504 opens and outputs the inverted signal of the match line ML. On the other hand, the inverter 506 does not output a signal to close. Therefore, when the control signal MAE is asserted, the data of the match line ML is transmitted to the match signal output line MLO and the All-Miss determination input AMI. If the control signal MAE is negated, the inverter 504 does not output a signal to close. Meanwhile, when the inverter 506 opens, it inverts the output signal of the inverter 505 and returns it to the inverter 505, while also outputting it to the inverter 507. Therefore, when the control signal MAE is negated, the signal levels of the match signal output line MLO and the All-Miss determination input AMI are held at their previous values.

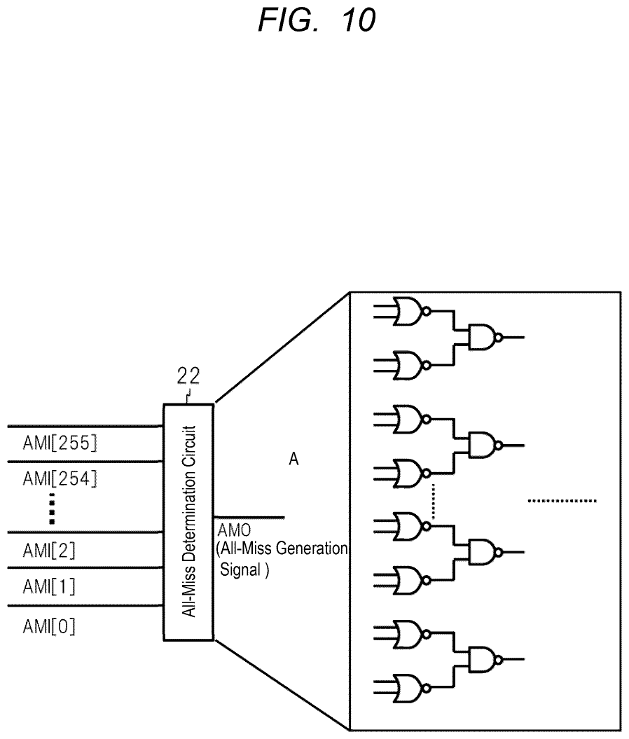

FIG. 10 is an example of the circuit of the All-Miss determination circuit 22. The All-Miss determination circuit 22 is a circuit that determines whether all the All-Miss determination inputs AMI [255:0] are mismatches (Miss). In other words, it determines whether all the match lines ML indicate a mismatch. At this time, if all entries inside the block are Lo (all mismatches), the All-Miss generation signal AMO outputs Lo. If there is even one match (Hit), the All-Miss generation signal AMO outputs Hi. FIG. 10 shows an example of a configuration using a multi-stage connection of NOR-NAND circuits, but other circuit configurations may be used as long as the above function can be realized.

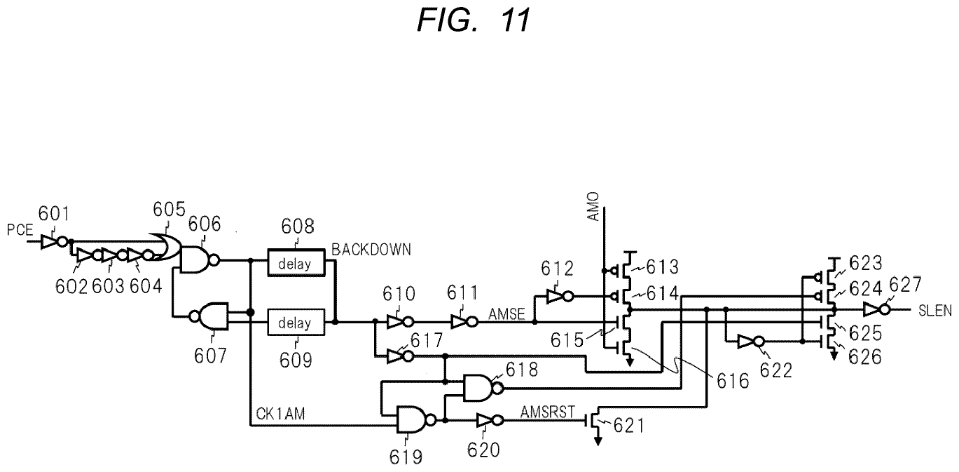

FIG. 11 is an example of the circuit of the SLEN generation circuit 23. The SLEN generation circuit 23 includes inverters 601, 602, 603, 604, 610, 611, 612, 617, 620, 622, 627, an OR circuit 605, NAND circuits 606, 607, 618, 619, delay circuits 608, 609, pMOS transistors 613, 614, 623, 624, and nMOS transistors 615, 616, 621, 625, 626.

The inverter 601 inverts the signal level of the control signal PCE and outputs it. The inverter 602 inverts the signal level of the control signal PCE and outputs it. The inverter 603 inverts the output signal level of the inverter 602 and outputs it. The inverter 604 inverts the output signal level of the inverter 604 and outputs it.

The OR circuit 605 receives the output signals of the inverter 601 and the inverter 604 and outputs the result of the OR logic operation. The NAND circuit 606 receives the output signals of the OR circuit 605 and the NAND circuit 607 and outputs the result of the NAND logic operation as the control signal CK1AM. The NAND circuit 607 receives the control signal CK1AM and the output signal of the delay circuit 609 and outputs the result of the NAND logic operation.

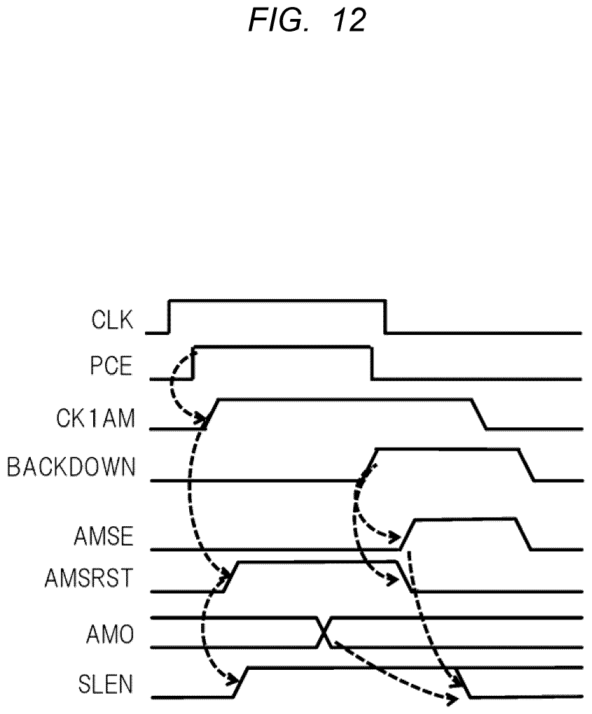

The delay circuit 608 delays the control signal CK1AM by a predetermined time and outputs it as the control signal BACKDOWN. The delay circuit 609 delays the control signal BACKDOWN by a predetermined time and outputs it. The delay time of the delay circuit 608 is preferably a time sufficient for the All-Miss generation signal AMO to be determined, as shown in FIG. 12.

The inverter 610 inverts the signal level of the control signal BACKDOWN and outputs it. The inverter 611 inverts the signal level of the inverter 610 and outputs it as the control signal AMSE. The inverter 612 inverts the signal level of the control signal AMSE and outputs it.

The pMOS transistors 613, 614 and the nMOS transistors 615, 616 are connected in series between the power supply potential (voltage Vcc level) and the ground potential (voltage Vss level). A control signal is output from the connection node between the pMOS transistor 614 and the nMOS transistor 615. Also, the All-Miss generation signal AMO is input to the gates of the pMOS transistor 613 and the nMOS transistor 616, the inverted signal of the control signal AMSE is input to the gate of the pMOS transistor 614, and the control signal AMSE is input to the gate of the nMOS transistor 615.

Inverter 617 inverts the signal level of the control signal BACKDOWN and outputs it. The NAND circuit 618 receives the output signals of the inverter 617 and the NAND circuit 619 and outputs the result of the NAND logic operation. The NAND circuit 619 receives the output signals of the inverter 617 and the control signal CK1AM and outputs the result of the NAND logic operation. The inverter 620 inverts the output signal of the NAND circuit 619 and outputs it as the control signal AMSRST.

The nMOS transistor 621 is connected between the power supply potential and the ground potential. The control signal AMSRST is input to the gate of the nMOS transistor 621.

The inverter 622 inverts the signal level of the control signal output from the connection node between the pMOS transistor 614 and the nMOS transistor 615 and outputs it.

The pMOS transistors 623, 624 and the nMOS transistors 625, 626 are connected in series between the power supply potential and the ground potential. A control signal is output from the connection node between the pMOS transistor 624 and the nMOS transistor 625. Also, the output signal of the inverter 622 is input to the gates of the pMOS transistor 623 and the nMOS transistor 626, the output signal of the NAND circuit 618 is input to the gate of the pMOS transistor 624, and the output signal of the inverter 617 is input to the gate of the nMOS transistor 625.

The inverter 627 inverts the signal level of the control signal output from the connection node between the pMOS transistor 624 and the nMOS transistor 625 and outputs it as the slave drive signal SLEN.

Here, the operation of the SLEN generation circuit 23 will be described with reference to the timing chart in FIG. 12. Each signal name shown in FIG. 12 is a control signal described in the above explanation. The SLEN generation circuit 23 shown in FIG. 11 is a circuit that generates the slave drive signal SLEN. It is a circuit that sets the slave drive signal SLEN to Hi based on the Hi (assert) of the control signal PCE generated by the timing generation circuit 211.

When the control signal PCE is asserted to Hi, the control signal AMSRST becomes Hi, and as a result, the nMOS transistor 621 turns on, forcibly setting the slave drive signal SLEN to Hi. On the other hand, since the control signal AMSE is Lo, the All-Miss generation signal AMO is not output as the slave drive signal SLEN. At the time when the control signal BACKDOWN becomes Hi via the delay circuit 608, the All-Miss generation signal AMO is transmitted to the slave drive signal SLEN. When the control signal PCE is negated, the control signal AMSRST becomes Lo, and since the control signal AMSE is Hi, the All-Miss generation signal AMO is output as the slave drive signal SLEN.

With the circuit shown in FIG. 11, the early activation of the Hi level (activation) of the slave drive signal SLEN is realized, and it is achieved that the result is transmitted to the slave drive signal SLEN after the match or mismatch in the search unit 21 is determined.

As described above, the SLEN generation circuit 23 functions as a drive control circuit that controls slave block 3 to be activated or deactivated by outputting the slave drive signal SLEN to the slave block 3.

### Operation of the Circuit of the Present Embodiment

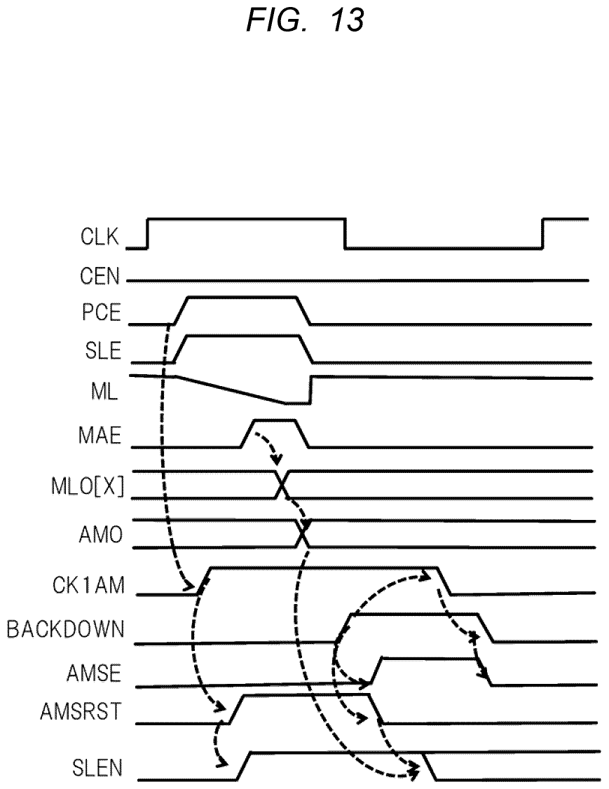

Next, the operation of the master block 2 with the above-described configuration will be described with reference to the timing chart in FIG. 13. With the rising edge of the clock signal CLK, the timing generation circuit 211 asserts the control signals PCE and SLE. When the control signal PCE is asserted, the precharge of the match line ML by the ML driver 213 is released. At the same time, the search line pair SL, SLB propagates the input (search data) from the data terminal D to the TCAM cell MC via the SL driver 212.

After the precharge is released and the search data is asserted on the search line pair SL, SLB, if there is a match (Hit), the match line ML holds Hi, and if there is a mismatch (Miss), the match line ML is pulled to Lo. At the time when the match line ML is sufficiently pulled, the timing generation circuit 211 asserts the control signal MAE, and the output of the match line ML is latched to the match signal output line MLO in the MLO Latch 214. Simultaneously with latching to the match signal output line MLO, the All-Miss determination circuit 22 determines whether all search results are mismatches.

When the control signal PCE is asserted, the control signal CK1AM is asserted in the SLEN generation circuit 23, and the slave drive signal SLEN is asserted to Hi. Therefore, even in the state where the match signal output line MLO is not output, the slave drive signal SLEN can be set to Hi. In other words, the slave block 3 can be activated. Subsequently, the control signal BACKDOWN becomes Hi via the delay circuit 608 from the control signal CK1AM. Then, the reset is released by setting the control signal AMSRST to Lo, and the All-Miss generation signal AMO is propagated to the slave drive signal SLEN. This determines whether to set the slave drive signal SLEN to Lo. The slave drive signal SLEN, which is determined to be set to Lo, is input to SLEN0 and SLEN1 of the slave block 3, determining whether the slave block 3 operates.

According to the above configuration, semiconductor device 1 includes a master block 2 that stores the first portion of a bit string constituting a data entry, and a slave block 3 that stores the remaining second portion excluding the first portion, having a memory array 4. Furthermore, it includes a search unit 21 that determines a match between any of the parts (multiple first portions) of the data entry stored in the master block 2 and the part corresponding to the first portion of the search data. The master block 2 controls the activation of the slave block 3 in response to the start of the determination by the search unit 21 and controls the continuation or deactivation of the slave block 3 based on the result of the determination by the search unit 21.

Therefore, in a circuit configuration where the operation of the slave block 3 is determined by the search result of the master block 2, the slave block 3 can be made operable in accordance with the operation of the master block 2. Thus, there is no need to wait for the search result of the master block 2, allowing the content addressable memory to operate faster.

The smaller the bit width of the master block 2, the smaller the load capacitance of the match line ML, allowing for faster operation. However, if the bit width of the master block 2 is small, the master block 2 is more likely to match, increasing the frequency of operation of the slave block 3 and reducing the power-saving effect. According to the configuration of this embodiment, it is possible to ensure the bit width of the master block 2 and reduce the frequency of operation of the slave block 3. Therefore, it is possible to achieve both speed and power reduction.

Additionally, the master block 2 has an SLEN generation circuit 23 that controls the activation or deactivation of the slave block by outputting a slave drive signal SLEN to the slave block 3. Therefore, the slave block 3 can be controlled by the slave drive signal SLEN according to the operation of the master block 2.

Furthermore, the slave block 3 includes multiple slave blocks 3a, 3b, each storing one of the multiple third portions constituting the second portion. For example, the slave block 3a determines a match between any of the third portions stored in itself and the part corresponding to the slave block 3a in the search data. The SLEN generation circuit 23 outputs the slave drive signal SLEN commonly to the slave blocks 3a, 3b. Therefore, even if the number of bits in an entry is large, it is possible to reduce the number of bits in the master block while optimizing the number of bits in each slave block. Thus, the master block 2 can be operated faster.

Additionally, a logical AND circuit 6 is further provided to determine the match between the search data and the data entry by the logical AND of the determination results of the master block 2 and the slave blocks 3a, 3b. Therefore, it is possible to output the match signal (match or mismatch) of the entire data entry divided into the master block 2 and the slave block 3.

Furthermore, the slave block 3 includes a search unit 31 that determines a match between any of the parts (multiple second portions) of the data entry stored in the slave block 3 and the part corresponding to the second portion of the search data, according to the determination in the master block 2. The search unit 31 performs the determination when the slave block 3 is activated by the master block 2 and does not perform the determination when the slave block 3 is deactivated. Therefore, the operation of the search unit 31 is determined by whether the slave block 3 is activated or not.

### Second Embodiment

Next, the second embodiment will be described. Note that the description of parts overlapping with the aforementioned embodiment will be omitted in principle.

### Configuration of This Embodiment

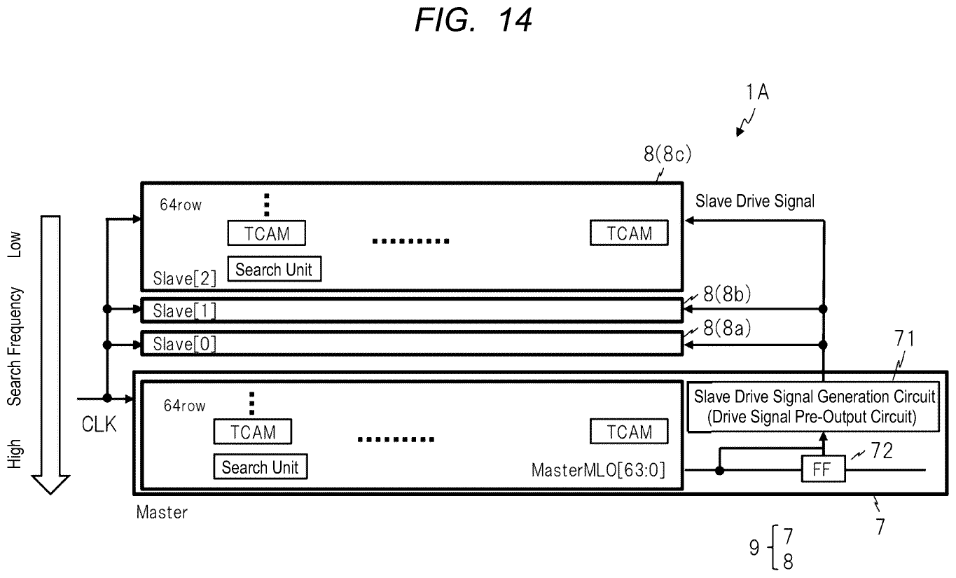

FIG. 14 shows a schematic diagram of a semiconductor device according to this embodiment. Semiconductor device 1A according to this embodiment sequentially performs search operations along the column direction on a memory array including multiple content addressable memory cells arranged in a matrix to store data entries, similar to the first embodiment. In this embodiment, the memory array is divided into multiple memory blocks in the row direction, which is different.

The content addressable memory of this embodiment will be described with reference to FIG. 14. Semiconductor device 1A (content addressable memory) includes a master block 7 and a slave block 8. The master block 7 and the slave block 8 together form the memory array 9.

The master block 7 has a memory array composed of, for example, 64-entry, 64-bit TCAM cells. The master block 7 also includes a slave drive signal generation circuit 71 and a master FF72.

The memory array of the master block 7 includes a circuit (search unit) with the same function as the search unit 21 described in the first embodiment. Master block 7 stores 64 entries of the entries stored in the memory array 9. That is, the master block 7 has a search circuit that determines a match between the search data and any of the first entry set, which is a set of entries stored in the master block 7. The master block 7 is designed to store data with high search frequency (high priority).

The slave drive signal generation circuit 71 outputs a slave drive signal to operate the search operation in the slave block 8 when all search results in the master block 7 are mismatches (Miss). The slave drive signal generation circuit 71 makes the slave block 8 operable in accordance with the start of operation of the master block 7, similar to the first embodiment, but in this embodiment, the slave block 8 is stopped when a match result is obtained in master block 7.

In other words, the slave drive signal generation circuit 71 controls the activation of the slave block 8 in response to the start of operation of the master block 7 and controls the continuation or deactivation of the slave block 8 based on the result of the determination by the search circuit in the master block 7.

Master FF72 is a register for delaying the search result of the master block 7 by one clock, similar to the first embodiment.

The slave block 8 has a memory array composed of, for example, 64-entry, 64-bit TCAM cells. In FIG. 14, the slave block 8 includes three slave blocks 8a, 8b, 8c, all of which have the same configuration. The slave block 8 stores the second entry set, which is the part of the data entries stored in the memory array 9 excluding the 64 entries of the first entry set.

According to the above configuration, semiconductor device 1A has a memory array of 9. The memory array 9 has a master block 7 that stores the first entry set, which is a set of some of the data entries. Furthermore, it has a slave block 8 that stores the second entry set, which is the set of the remaining data entries excluding the first entry set. Master block 7 has a search circuit that determines a match between any of the first entry set and the search data. Master block 7 controls the activation of the slave block 8 in response to the start of determination by the search circuit and controls the continuation or deactivation of the slave block 8 based on the result of the determination by the search circuit.

Therefore, similar to the first embodiment, in a circuit configuration where the operation of the slave block 3 is determined by the search result of the master block 7, the slave block 3 can be made operable in accordance with the operation of the master block 7, allowing the content addressable memory to operate faster without waiting for the search result of the master block.

Furthermore, by storing data with high search frequency in the master block 7, the frequency of stopping the slave block 8 can be increased, achieving power reduction.

In the case of content addressable memory, whether the slave block can be stopped depends on how much the master block matches (Hit). By dividing in the entry direction as in this embodiment, data that is easy to hit can be stored in the master block. Therefore, by adopting the configuration of this embodiment, the frequency of stopping the slave block can be increased.

### Application Example

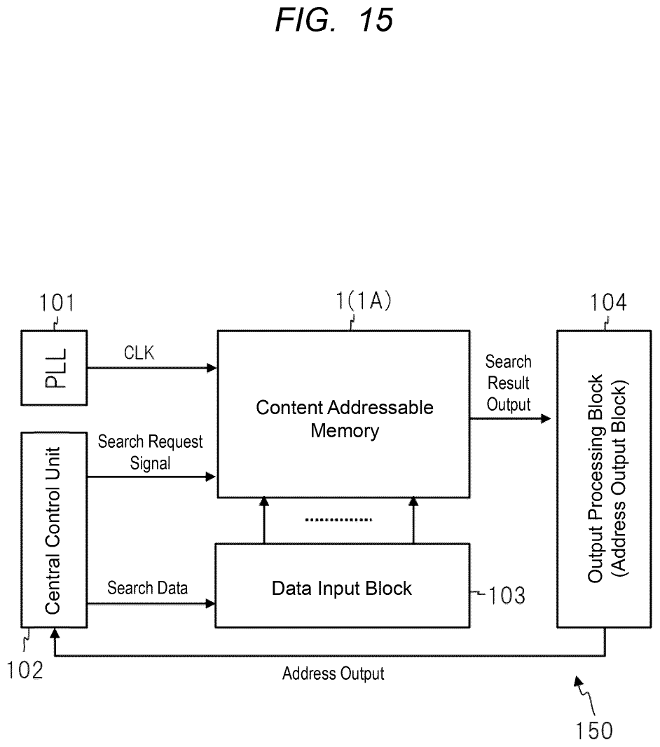

Finally, an application example of the above-described embodiment will be explained. The semiconductor device 1 or 1A (content addressable memory) shown in FIG. 1 or FIG. 14 can be used for address lookup and access control in routers for networks such as the Internet. An example of an address lookup system within a router using the semiconductor device 1 or 1A is shown in FIG. 15.

The address lookup system 150 shown in FIG. 15 includes the semiconductor device 1 or 1A, a PLL 101, a central control unit 102, a data input block 103, and an output processing block 104.

The PLL 101 is a well-known phase-locked loop circuit that outputs a clock signal CLK to the semiconductor device 1 or 1A. The central control unit 102 outputs a search request signal to the semiconductor device 1 or 1A. Additionally, the central control unit 102 outputs search data to the data input block.

The data input block 103 outputs the search data input from the central control unit 102 to the semiconductor device 1 or 1A. The output processing block outputs the matched (Hit) address to the central control unit 102 based on the search results output from the semiconductor device 1 or 1A.

The address lookup system 150 shown in FIG. 15 has network data such as IP addresses stored in advance. After starting the search operation, the central control unit 102 inputs a search request signal to the semiconductor device 1 or 1A and simultaneously inputs the data to be searched from the data input block 103 to the semiconductor device 1 or 1A. The semiconductor device 1 or 1A compares the data stored in the memory array with the data to be searched and passes all matched addresses to the output processing block 104. The output processing block 104 outputs the highest priority corresponding address to the central control unit 102. The priority may be determined by arranging high-priority information at lower addresses in the memory array or by using a priority encoder or the like.

Although the invention made by the present inventor has been specifically described based on the embodiment, the present invention is not limited to the embodiment described above, and it is needless to say that various modifications can be made without departing from the gist thereof.

What is claimed is:

1. A semiconductor device including a content addressable memory configured to determine a match between multiple data entries stored internally and at least a part of search data input from outside, comprising a memory array including a first block storing a first portion of a bit string constituting the data entries, and a second block storing a second portion excluding the first portion of the bit string,
wherein the first block includes a first search circuit to determine a match between any of the first portions and a portion corresponding to the first portion of the search data, and
wherein the first block controls to activate the second block in response to the start of determination by the first search circuit, and controls to continue the activation or inactivate the second block according to the result of the determination by the first search circuit.

2. The semiconductor device according to claim 1, wherein the first block has a drive control circuit that controls the second block to activate or inactivate by outputting a drive signal to the second block.

3. The semiconductor device according to claim 2, wherein the second block has multiple sub-blocks each storing one of multiple third portions constituting the second portion, and the sub-blocks determine a match between any of the third portions and a portion corresponding to the third portion of the search data, and the drive control circuit outputs the drive signal to the multiple sub-blocks to control the sub-blocks to activate or inactivate.

4. The semiconductor device, according to claim 3, further comprising a match detection circuit that determines a match between the search data and the data entries by a logical product of the determination result of the first block and the determination results of the multiple sub-blocks.

5. The semiconductor device according to claim 1, wherein the second block includes a second search circuit that determines a match between any of the second portions and a portion corresponding to the second portion of the search data according to the determination in the first block, and the second search circuit performs the determination when the second block is activated by the first block and does not perform the determination when the second block is inactivated by the first block.

6. A semiconductor device including a content addressable memory configured to determine a match between multiple data entries stored internally and at least a part of search data input from outside, comprising a memory array including a first block storing a first entry set which is a set of part of the data entries, and a second block storing a second entry set excluding the first entry set from the multiple data entries,
wherein the first block includes a first search circuit to determine a match between any of the first entry set and the search data, and
wherein the first block controls to activate the second block in response to the start of determination by the first search circuit, and controls to continue the activation or inactivate the second block according to the result of the determination by the first search circuit.
